(19) United States
(12) Patent Application Publication
(10) Pub. No.: US 2006/0232777 A1
(43) Pub. Date: Oct. 19, 2006

(54) Method and system for automatic target finding

(76) Inventors: Moshe Finarov, Rehovot (IL); Ido Hocman, Rehovot (IL)

Correspondence Address: David Klein;Beit HaRofim, 18 Menuha Venahala Street, Room 27, Rehovot, 76209, IL

(21) Appl. No.: 10/569,466

(22) PCT Filed: Jun. 17, 2004
(86) PCT No.: PCT/IL04/00525

§ 371 Date: Feb. 24, 2006

(30) Foreign Application Priority Data
Jun. 23, 2003 (IL) 156589

(51) Int. Cl. G01B 11/00

(52) U.S. Cl. 356/401

(57) ABSTRACT

A method and system are presented for automatic target finding by using two imaging channels with relatively low and high magnifications, using the low magnification channel (relatively large field of view) for finding a region of interest (i.e., that of the targets location within the field), scanning this zone by grabbing images via the high magnification channel (relatively small field of view) and marking the overlay targets using image processing algorithms.

### FIELD OF THE INVENTION

This invention is generally in the field of optical metrology and relates to a target finding method and system, particularly useful for controlling overlay registration in patterned articles.

### BACKGROUND OF THE INVENTION

Monitoring of patterns' alignment (the commonly used specific term is “overlay registration” or “overlay”) is widely used in the manufacture of integrated circuits. The latter are multi-layer structures, which are produced by applying a sequence of deposition-lithography-etching steps to a semiconductor wafer. These processes require precise alignment of layers with respect to each other. The quality of alignment between pattered layers is typically controlled by overlay registration metrology.

There are a few types of overlay targets used in the conventional optical methods that allow precise measurement of the overlay registration. These are the so-called Box-in-Box, Frame-in-Frame, Bars-in-Bars, Box-in-Frame, and Box-in-Bars targets. All the target types share the same basic topology of inner and outer rectangles, one is printed in a previous step and the other in the current production step. The common target size is 20-25 μm for the outer rectangle and 10-15 μm for the inner rectangle. According to this technique, a rectangular frame-like structure (target) is formed in a test site of each layer, and two locally adjacent layers (typically spaced by a dielectric layer) are considered as being correctly aligned if a specific alignment between the targets in the test sites is provided. Overlay defining the alignment is measured by comparing shifts between the targets along two mutually perpendicular axes, i.e., determining whether the targets are precisely concentric, the smaller target being inside the larger one (in projection along a vertical axis). Thus, the box-in-box test patterns (targets) are imaged by high magnification optical microscope, where outer and inner boxes of the target represent positions of two different layers, respectively, of the wafer, and a displacement between these two boxes is indicative of the measured overlay. Machines utilizing this optical technique have been developed and are commercially available from KLA-Tencor (5xxx & Archer 10XT), Accent Optical Technologies (Caliper & Q200), Nikon (NRM-3000), Nova Measuring Instruments (NovaTrack 2020), etc.

Various overlay measurement techniques are described, for example, in U.S. Pat. No. 6,166,801, assigned to the assignee of the present application

The main principles of the conventional technique are schematically illustrated in FIGS. 1A and 1B (exemplifying a Bar-in-Bar based technique). Bar 1 and Bar 2 are structures of different sizes and identical geometry and are formed in test sites of different layers. As shown in FIG. 1A, the registration between these layers is considered perfect, when imaging of these bars show that the centers of the bars are located in the same place, i.e., zero overlay of the bars along the X- and Y-axes (OLₓ=OL_{y}=0). As shown in FIG. 1B in dashed lines, if the image of the layer 1 (Box 1) is shifted relative to layer 2 (Box 2), the degree of misregistration is measured by the overlay value OL (OLₓ in the figure).

Box-in-box (or the like) targets for overlay measurements are usually located within the junctions of the periphery of the field of an exposure tool, e.g., stepper. Such a field usually includes several dies, and is currently of about 25 mm (typical size) in each dimension. This is schematically illustrated in FIGS. 2A and 2B, wherein FIG. 2A shows a die map in the form of the distribution of dies over a wafer, and FIG. 2B more specifically shows a junction region of the die map with a target located therein. The distribution of dies over the wafer depends among others on the following factors: the die size, the street (scribe line) size, pattern centering on the wafer, and edge exclusion. Die maps for different products (chip designs) may be different. The location of box-in-box (or the like) targets within the scribe lines or junctions may also be different, depending on the wafer design. When wafers are manufactured by independent chipmakers (foundary), different customers may locate their targets and test sites for process control differently. When a new product is introduced, it is necessary to build the so-called “recipe” for each measurement tool, including overlay measurement tool that defines location of the targets on a wafer and measurement conditions allowing proper metrology.

### SUMMARY OF THE INVENTION

There is a need in the art to facilitate overlay measurements by providing a novel method and system that ensure automatic target finding (e.g., box-in-box target) and recipe design utilizing the same.

The problem to be solved by the present invention is associated with the following: During overlay recipe setup, one must find and identify the overlay targets. The latter are rectangular with a size of about 25 μm. It is impossible to identify the target using the coarse field of view of a size covering several dies (pixel size of about 40 μm). Trying to locate the target with the fine field of view, such as that of the microscope optics (field of view size of about 100 μm) without prior knowledge of the targets' coordinates relative to the field is a very tedious assignment, requiring many step-and-repeat relative displacements between the wafer and the microscope’ field of view. With a stand-alone tool, various optical magnifications with different field of view values can easily be used, thereby accelerating the target search. However, when operating with an integrated metrology tool that, because of size constrains, has an optical system with only two different magnifications, such a search might be time consuming.

The present invention solves the above problem and provides for recipe design utilizing automatic target finding by using two imaging channels with relatively low and high magnifications, using the low magnification channel (relatively large field of view) for finding a region of interest (i.e., that of the targets location within the field), scanning this zone by grabbing images via the high magnification channel (relatively small field of view) and marking the overlay targets using image processing algorithms.

Thus, according to one broad aspect of the invention, there is provided a method for automatic identification of a target on a patterned article, which contains targets located in spaces between periodically repeated patterned fields, the method comprising:
first imaging the article with relatively low magnification defining a first field of view, and generating first measured data indicative thereof;
analyzing the first measured data to identify a region of interest within the first field of view, said region of interest being that of a potential location of the target;
applying an area imaging device having relatively high magnification defining a second field of view, to scan the region of interest with a predetermined speed of scanning and a predetermined rate of image acquisition during the scanning, and generating second measured data indicative of a high resolution image of the region of interest;
analyzing the second measured data to identify the existence of the target in a location in said region of interest, thereby enabling high magnification imaging of the identified target location and determination of coordinates of said location.

The second measured data indicative of the high resolution image of the region of interest is obtained by stitching the high magnification images acquired during the scanning. This high resolution image is thus smeared, because the images are grabbed while moving. The data analysis provides for identifying a possible position of targets. Further acquiring the high magnification image of this location provides for verifying the target position and determining its coordinates.

The field of view of the low magnification channel is such as to include at least one field of view of the exposure tool (FOV of about 40 μm), and the field of view of the high magnification channel is such as to include at least one of the searched targets (FOV of about 100 μm). An optical system utilizing such high and low magnification channels suitable for use in overlay measurements is disclosed in the above-indicated U.S. Pat. No. 6,166,801, assigned to the assignee of the present application.

According to another broad aspect of the present invention, there is provided a method for creating a recipe for use in processing a patterned article, which contains targets located in spaces between periodically repeated patterned fields, the method comprising identifying at least one target on the article and recording the target location, wherein said identifying comprises:
first imaging the article with relatively low magnification defining a first field of view, and generating first measured data indicative thereof;
analyzing the first measured data to identify a region of interest within the first field of view, said region of interest being that of a potential location of the target;
applying an area imaging device having relatively high magnification defining a second field of view, to scan the region of interest with a predetermined speed of scanning and a predetermined rate of image acquisition during the scanning, and generating second measured data indicative of a high resolution image of the region of interest;
analyzing the second measured data to identify the existence of the target in a location in said region of interest, thereby enabling high magnification imaging of the identified target location to verify the target location and determine coordinates of said location.

According to yet another aspect of the present invention, there is provided a system for use in automatic identification of a target on a patterned article, which contains targets located in spaces between periodically repeated patterned fields, the system comprising:
a measuring unit including an optical arrangement defining a relatively low-magnification imaging channel and a relatively high-magnification imaging channel, wherein said relatively high-magnification imaging channel includes an area imaging device;
a drive assembly operable to provide a relative displacement between an optical head of said measuring unit and the article in a horizontal plane; and
a control unit connectable to the measuring unit and to the drive assembly, said control unit being preprogrammed for:
   operating the measuring unit to apply first imaging of the article with the relatively low magnification and generate first measured data indicative of a region of interest on the article,
   for operating the measuring unit and the drive assembly to apply the high-magnification scanning of the region of interest with a predetermined speed of scanning and a predetermined rate of image acquisition during the scanning and generate second measured data representative of a high resolution image of the region of interest, and
   for analyzing the second measured data to identify the existence of the target in a location in said region of interest, thereby enabling high magnification imaging of the identified target location to verify the target location and determine coordinates of said location.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIGS. 1A and 1B schematically illustrate the main principles of the conventional bar-in-bar (or the like) overlay measurement technique;

FIGS. 2A and 2B schematically illustrate a die map in the form of the distribution of dies over a wafer, with a target located in a junction between the scribe lines;

FIG. 3 schematically illustrates a measurement system according to the invention;

FIG. 4 exemplifies a possible implementation of a measuring unit in the system of FIG. 3; and

FIG. 5 illustrates a flow diagram of the main operation steps of a method of the present invention.

### DETAILED DESCRIPTION OF THE INVENTION

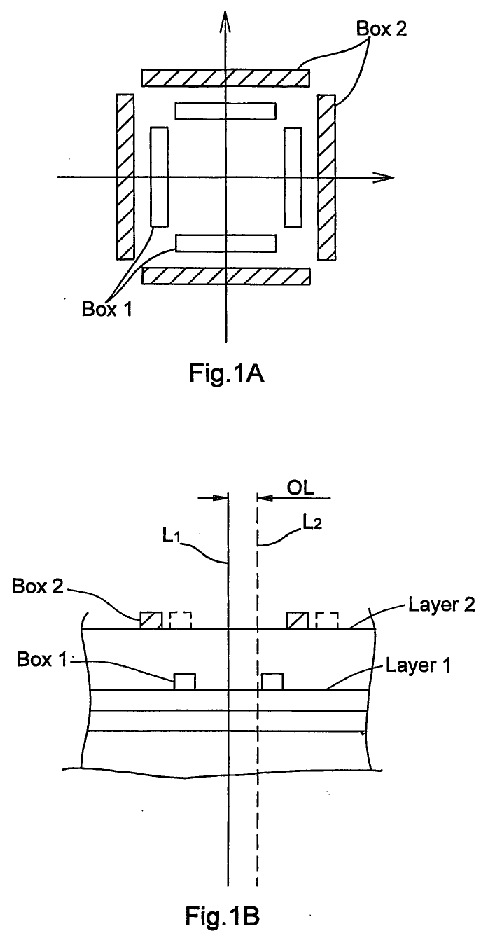

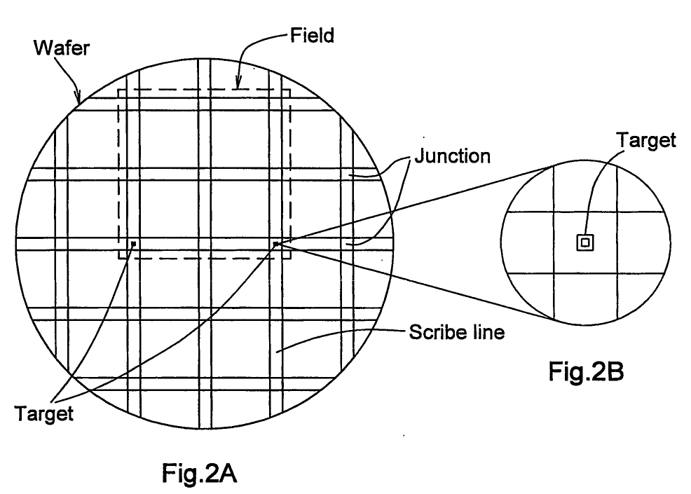

FIGS. 1A and 1B illustrate a bar-in-bar target structure, showing a perfect alignment (registration) between two patterned target-containing layers (when the centers of the bars are located in the same place) and a misregistration between the layers (when the image of one target is shifted relative to that of the other). FIGS. 2A and 2B illustrate a die map in the form of the distribution of dies over a wafer. A box-on-box target is typically located in a junction region of the die map.

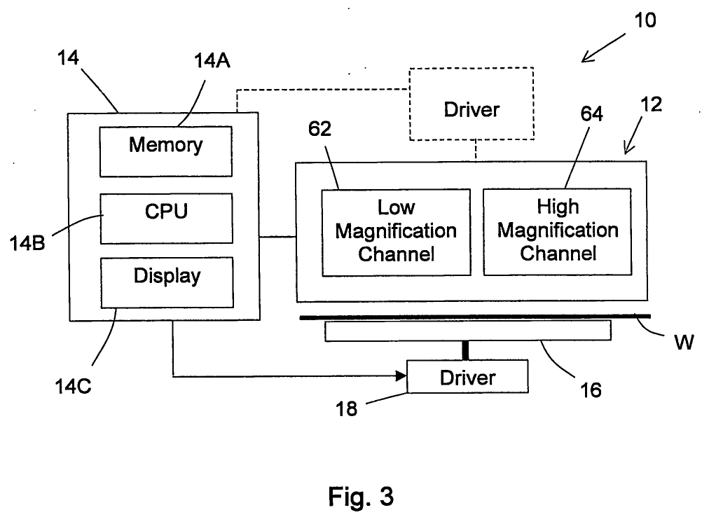

Referring to FIG. 3, there is schematically illustrated a measurement system 10 according to the invention for overlay measurements on a wafer W. The system 10 comprises such main constructional parts as a measuring unit 12 and a control unit 14.

The measuring unit 12 includes an optical arrangement defining two light propagation channels of different image magnifications—a relatively low magnification channel 62 (e.g. 0.3-1.0×.) and a relatively high magnification channel 64 (e.g., 20-100×). For example, the measuring unit may be constructed and operated as described in the above-indicated U.S. Pat. No. 6,166,801 assigned to the assignee of the present application. The control unit is a computer system including inter alia a memory utility 14A, data processing and analyzing utility 14B and an output data representing utility (e.g., display) 14C.

The wafer is typically located on a support stage 16. A drive mechanism 18 is provided being associated with the stage 16 or/and the optics of the measuring unit 12, and is operable by the control unit 14 to provide a relative displacement between the wafer and the optics in a horizontal plane.

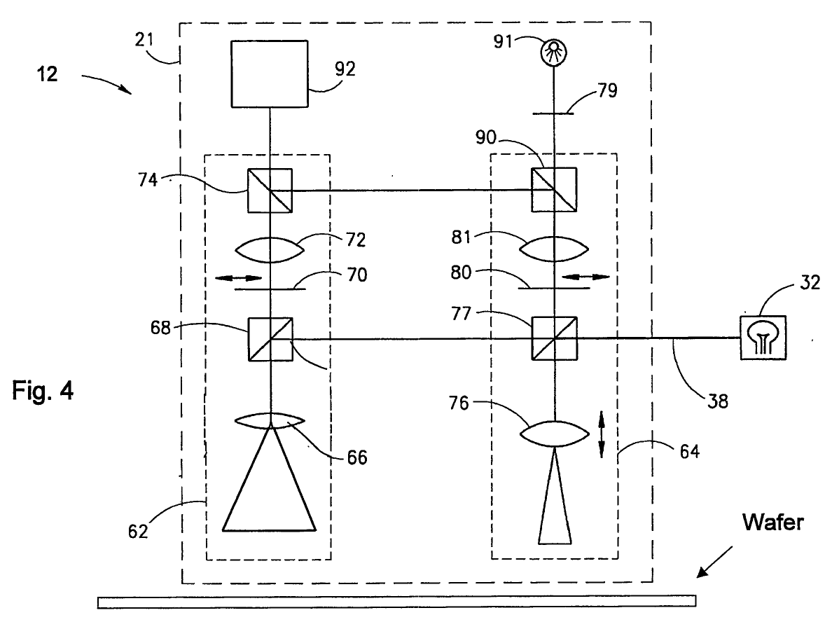

FIG. 4 illustrates the construction of the measuring unit 12 as described in the above-indicated patent. The measuring unit 12 is composed of two light propagation channels: a low-magnification channel 62 and a high-magnification channel 64. In the present example, both channels utilize a common light source 32 and a common detector 92 (area CCD camera). The low-magnification channel 62 is formed by an objective 66, a beam splitter 68, a shutter 70, a tube lens 72 and a beam splitter 74. The objective 66, which is part of a movable optical head, has a small numerical aperture and images a wide field of view (e.g., 20-40 mm). The high-magnification channel 64 comprises a vertically movable objective 76 that is part of the movable optical head, a beam splitter 77, a shutter 80, a tube lens 81, a beam splitter 90, a focusing target 79 (any high contrast object, such as a metallic pattern on a glass substrate, e.g., as a contrast edge, a grid, etc), and an illuminator 91 (e.g., LED). The objective 76 has large numerical aperture since high resolution is needed, and images a relatively small field of view (about 100 μm). The focusing target 79 is installed in the optical path with the option of removing it when not needed (movable target), or of locating its image in the CCD 92 plane in such a way which does not interfere with the imaged wafer or imaged overlay targets.

Suitable means are provided to enable selection between operating either one of the channels 62 and 64. In the present example, the selection is realized by shutters 70 and 80 that can be selectively opened or closed. As also disclosed in the above-indicated patent, the low-magnification channel 62 and the high-resolution channel 64, as well as the focusing target 79 and LED 91 can be contained within the movable optical head.

Referring back to FIGS. 2A and 2B, targets are in the shape of rectangles (an inner bar having about 10-15 μm dimensions and an outer one—20-25 μm) and are located in the scribe lines (of about 80-100 μm width) around a field area (i.e., field of view of an exposure tool). In some cases, there are targets in the scribe line near the center of the field area. Targets assigned to neighboring fields are located in the same scribe line (thus, 1-2 scribe lines are to be scanned in order to locate all the targets).

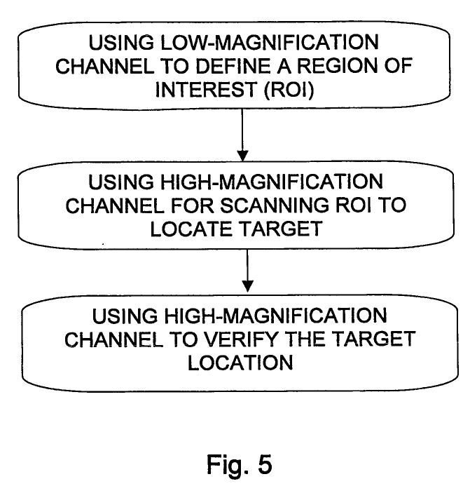

The operation of the system of the present invention will now be described with reference to FIG. 5:

Step I—The low-magnification channel 62 and the control unit 14 are operated to define a region of interest (search zone) on the wafer. This is implemented by imaging the wafer with the relatively large field of view, generating measured data indicative thereof (constituting first measured data), and processing this data to recognize boundaries of the exposure field, and thus find a region of interest, i.e., the scribe lines and junctions where the targets are expected. Such recognition is possible due to the fact that the field usually includes specific features needed for the exposure tool alignment and further overlay measurements.

Step II—The high magnification channel 64 and the control unit 14 are operated (relatively small field of view) to enable marking of the optional target position. To this end, the previously determined region of interest (scribe line) is scanned while grabbing images every 25 μm with a two-dimensional pixel-array detector (area CCD). Data indicative of these images is processed using blob analysis to thereby find and mark shapes in each image. Generally, this can be done by running an edge detection filter on the image and marking every closed shape as a blob. For the purposes of the present invention, edge detection filters can be run on the image and only pixels that passed a predefined threshold can be shown, thus marking the edges of every line in the image. By utilizing a method of dilation and erosion, the edges of every shape in the image will form a closed pattern. Analysis of the closed patterned shape will mark rectangles only. The algorithm will mark rectangles that have dimensions similar to those of the overlay targets. By this, rectangular blocks can be located and marked, i.e., their coordinates relative to the field corner can be calculated.

More specifically, the above is implemented as follows: A relative displacement between the wafer and the optics is provided along the first marginal scribe line with a certain substantially constant speed. Pictures are continuously grabbed by the imaging device during this movement. For each acquired picture, image processing algorithms are applied in order to recognize the target. An image processing technique, consisting of stitching the so-grabbed high magnification images, results in a high resolution image of the region of interest.

It should be noted that this high resolution image acquired during a continuous movement (scanning) may be blurred to some extent along the axis of movement. The degree of blurring depends on the image acquisition time (integration time in the case of CCD) and the speed of movement. Since a box-in-box (or the like) target is usually much larger in size than the detector's pixel, some limited blurring may be acceptable. Owing to the fact that at this stage of target identification only a coarse positioning of the target is needed, the target image quality is not as critical as that of the case of precise measurements. It should be noted that, while an image acquired during a movement along one axis is blurred, the image along the other axis is abrupt. This is helpful for the target pattern recognition during the movement. It should be emphasized that such a novel approach as continuous scanning with an area sensor (e.g. CCD) enables high speed scanning on account of allowed level of image blurring.

Step III—Having scanned each region of interest, the system jumps to every position that has been marked during step II as a possible target.

Step IV—Steps II and III are repeated for all the region of interests until the targets are found. The high magnification channel 64 and the control unit 14 operate to verify the target position. The target is imaged with a high quality while at the stationary position of the wafer with respect to the imaging device. This enables to accurately calculate the coordinates of the target and store these coordinates in a product measurement recipe. If the target is not recognized during this scan, the scanning step is repeated for another marginal scribe line on the field until at least one of the targets in the selected field is detected. The determination of the coordinates of the target is based on locating the rectangular blobs (a closed shape in the image that has been found in the image by applying the edge detection technique and some predefined threshold), and comparing the target characteristics (number of rectangles, rectangle size, etc.), or by correlation to a synthetic target image or a golden target (i.e., a similar target image that has been grabbed from another wafer). This procedure may also include analyzing known marks, if any (using optical characteristic recognition (OCR) to match the layer name), or a pattern recognition technique to positively verify the target existence by comparing the acquired image to that of a golden target (e.g., taken form another product in the same production stage). Then, the positively identified targets may be accepted.

Preferably, the method also comprises the following steps: The targets are assigned to the respective field according to their coordinates relative to the field corner. The target coordinates are approved: an image of the target coordinates' zone is grabbed, and the target existence is verified in the above-described manner.

Thus, the technique of the present invention provides for automatically searching for a target by using two optical channels that are designed for the overlay measurements and alignment and based on an area imaging device (e.g., CCD).

The following is a specific not-limiting example of using the technique of the present invention in an integrated metrology tool or overlay measurement tool.

The fields of views for low and high magnification channels are, respectively, FOV_{L}=40 mm and FOV_{H}=100 μm. The pixel sizes of the images acquired with the low and high magnification channels are, respectively, P_{L}=40 μm and P_{H}=0.1 μm. The field size (defined by the exposure tool) is 25×25 mm. The CCD integrated time is IT=1 msec, the CCD frequency is 30 Hz, and the CCD cycle time is thus τ=30 msec. Considering the allowed image blurring of 5 pixels, the maximal allowed speed of movement (wafer relative to the optics or vice versa) is determined as:

$$V = \frac{5 \cdot 0.1 μ m}{1 m sec} = \frac{0.0005}{0.001} mm / sec \approx 0.5 mm sec$$

In this case, the scan time for one marginal scribe line of the field is: T≈(25 mm)/(0.5 mm/sec)=50 sec.

A number of scans required for the reliable target detection is 2. Hence, the total time for the target detection is 100 seconds.

Since the CCD integrated time IT is much smaller than the CCD cycle time τ, IT<τ, the minimum distance between images will be τ·V=30(msec)·0.5(mm/sec)=15 μm. This will ensure overlapping between the images during scanning. Blurring can be significantly higher without loosing much information (up to about 15 μm). Hence, the maximum scanning velocity can be 1.5 mm/sec. The scan time for one scribe line is much smaller, i.e., only 16.6 sec.

It is thus evident that the recipe design technique of the present invention is sufficiently quick and can thus be advantageously used while measuring on semiconductor wafers progressing on a production line, even in the case of frequently changeable product designs (such as in case of foundries).

Those skilled in the art will readily appreciate that various modifications and changes can be applied to the embodiment of the invention as herein before exemplified without departing from its scope as defined in and by the appended claims. For example, the measuring unit can utilize any other suitable optical system designed so as to enable imaging with relatively low magnification, and relatively high magnification scanning with an area detector.

1. A method for automatic identification of a target on a patterned article, which contains targets located in spaces between periodically repeated patterned fields, the method comprising:
first imaging the article with relatively low magnification defining a first field of view, and generating first measured data indicative thereof;
analyzing the first measured data to identify a region of interest within the first field of view, said region of interest being that of a potential location of the target;
applying an area imaging device having relatively high magnification defining a second field of view, to scan the region of interest with a predetermined speed of scanning and a predetermined rate of image acquisition during the scanning, and generating second measured data indicative of a high resolution image of the region of interest;
analyzing the second measured data to identify the existence of the target in a location in said region of interest, thereby enabling high magnification imaging of the identified target location to verify the target location and determine coordinates of said location.

2. The method of claim 1, wherein said field on the article includes a two-dimensional array of features of the pattern spaced by intersecting scribe lines defining junctions.

3. The method of claim 1 wherein said first field of view has a size including that of at least one of said fields on the article.

4. The method of claim 1 for use with semiconductor wafers, said first field of view being of about 40 mm.

5. The method of claim 1 wherein said second field of view has a size including that of at least one of the targets.

6. The method of claim 5 for use with semiconductor wafers, said second field of view being of about 100 μm.

7. The method of claim 2 wherein the analyzing of the first measured data includes identifying the scribe lines and the junctions where the targets are expected.

8. The method of claim 1 wherein the second measured data is obtained by applying blob analysis to data indicative of the images acquired during the scanning.

9. The method of claim 2 wherein said scanning is carried out along the scribe line, said speed being defined by an acceptable degree of image blurring is said high resolution image.

10. The method of claim 1 comprising assigning the identified target to the respective field on the article according to the target's coordinates relative to a corner of the field.

11. The method of claim 10 comprising approving the target coordinates by grabbing images of the target coordinates' location on the article with the high magnification imaging, and verifying the target existence.

12. A method for creating a recipe for use in processing a patterned article, which contains targets located in spaces between periodically repeated patterned fields, the method comprising identifying at least one target on the article and recording the target location, wherein said identifying comprises:
first imaging the article with relatively low magnification defining a first field of view, and generating first measured data indicative thereof;
analyzing the first measured data to identify a region of interest within the first field of view, said region of interest being that of a potential location of the target;
applying an area imaging device having relatively high magnification defining a second field of view, to scan the region of interest with a predetermined speed of scanning and a predetermined rate of image acquisition during the scanning, and generating second measured data indicative of a high resolution image of the region of interest;
analyzing the second measured data to identify the existence of the target in a location in said region of interest, thereby enabling high magnification imaging of the identified target location to verify the target location and determine coordinates of said location.

13. The method of claim 12 comprising approving the target coordinates by grabbing images of the target coordinates' location on the article with the high magnification imaging, and verifying the target existence.

14. A system for use in automatic identification of a target on a patterned article, which contains targets located in spaces between periodically repeated patterned fields, the system comprising:
a measuring unit including an optical arrangement defining a relatively low-magnification imaging channel and a relatively high-magnification imaging channel, wherein said relatively high-magnification imaging channel includes an area imaging device;
a drive assembly operable to provide a relative displacement between an optical head of said measuring unit and the article in a horizontal plane; and
a control unit connectable to the measuring unit and to the drive assembly, said control unit being preprogrammed for:
operating the measuring unit to apply first imaging of the article with the relatively low magnification and generate first measured data indicative of a region of interest on the article,
for operating the measuring unit and the drive assembly to apply the high-magnification scanning of the region of interest with a predetermined speed of scanning and a predetermined rate of image acquisition during the scanning and generate second measured data representative of a high resolution image of the region of interest, and
for analyzing the second measured data to identify the existence of the target in a location in said region of interest, thereby enabling high magnification imaging of the identified target location to verify the target location and determine coordinates of said location.
